(19) United States
(12) Patent Application Publication
(10) Pub. No.: US 2023/0032184 A1
(43) Pub. Date: Feb. 2, 2023

(54) ELECTROMAGNETIC SEPARATION TYPE COATING DEVICE AND METHOD

(71) Applicant: Lanzhou Institute of Chemical Physics, Chinese Academy of Sciences, Lanzhou City (CN)

(72) Inventors: Bin ZHANG, Lanzhou City (CN); Qian JIA, Lanzhou City (CN); Junyan ZHANG, Lanzhou City (CN); Kaixiong GAO, Lanzhou City (CN)

(21) Appl. No.: 17/704,994

(22) Filed: Mar. 25, 2022

(30) Foreign Application Priority Data
Jul. 29, 2021 (CN) 202110864919.5

(51) Int. Cl. C23C 14/35; C23C 14/56

(52) U.S. Cl. CPC C23C 14/35; C23C 14/56

(57) ABSTRACT

An electromagnetic separation type coating device is provided, and belongs to the technical field of vacuum coating. The device comprises a main vacuum cavity, the front side and the rear side of the main vacuum cavity are each provided with a vacuum cavity door, middle positions of the front vacuum cavity door and the rear vacuum cavity door are each provided with a set of magnetron sputtering targets, and the two sets of magnetron sputtering targets are symmetrically arranged; two sets of ion sources are symmetrically arranged on the outer walls of the left side and the right side of the main vacuum cavity, and two sets of magnetic induction coils are symmetrically arranged at two sides of each set of ion sources, respectively; a vacuum pump set is connected to the top of the main vacuum cavity, a workpiece rest is installed at the bottom in the main vacuum cavity, and is used for installing a to-be-deposited sample piece; and an auxiliary anode is further installed in the main vacuum cavity. An electromagnetic separation type coating method is further provided. The electromagnetic separation type coating device and method provided by the present disclosure have the advantages of effectively improving the three-dimensional space plasma density, increasing ion energy, and obtaining a thin film with excellent performance.

### TECHNICAL FIELD

The present disclosure relates to the technical field of vacuum coating, and in particular relates to an electromagnetic separation type coating device and method.

### BACKGROUND ART

Vacuum coating technology is a material surface treatment technology and is commonly used in the aspects of decoration, optics, electrical properties, machinery, and corrosion. The vacuum coating technologies include vacuum evaporation coating, vacuum sputtering coating, vacuum ion coating, vacuum winding coating, a chemical vapor deposition CVD technology, an ion implantation and ion-assisted deposition technology and the like. A variety of coating technologies have emerged to meet different application requirements and to improve the performance of a coated thin film, especially for the increasing performance requirements of the thin films, which requires progress in improving the coating technology.

The Chinese patent application CN108048795A discloses a surface coating process for a mechanical part, through which a pattern can be formed on the surface of the part without cutting or carving. The patent ZL20161090681.6 discloses a magnetic pole-assisted unbalanced magnetron sputtering system, which improves the structure controllability of the coating and the uniformity of the coating thickness. The Chinese patent ZL200910074779.0 discloses a method for preparing a chromium-aluminum-nitrogen thin film through closed field unbalanced magnetron sputtering, through which the hardness, strength and wear resistance of the surface of high chromium-tungsten-manganese steel are effectively improved. The Chinese patent ZL201310729760.1 discloses a high-power pulse magnetron sputtering-excited/anode layer ion source-assisted magnetron sputtering coating device, which greatly improves the binding force and strength of a thin film.

In the prior art, the high-power pulse magnetron sputtering is high in ionization rate and ion energy, but low in deposition efficiency, while the magnetron sputtering has the problems of high deposition but low ionization rate ion energy, difficulty in obtaining dense thin films, easy poisoning of target space, and small process range.

Hence, the providing of a novel electromagnetic separation type coating device to solve the defects in the prior art has become a technical problem urgent to be solved.

### SUMMARY

An objective of the present disclosure is to provide an electromagnetic separation type coating device and method to solve the problems in the prior art, which can effectively improve three-dimensional space plasma density, increase the ion energy, and obtain a thin film with excellent performance.

To achieve the objective, the present disclosure provides the following solutions: an electromagnetic separation type coating device is provided, comprising a main vacuum cavity, wherein the front side and the rear side of the main vacuum cavity are each provided with a vacuum cavity door, middle positions of the front vacuum cavity door and the rear vacuum cavity door are each provided with a set of magnetron sputtering targets, and the two sets of magnetron sputtering targets are symmetrically arranged; two sets of ion sources are symmetrically arranged on the outer walls of the left side and the right side of the main vacuum cavity, and two sets of magnetic induction coils are symmetrically arranged at the two sides of each set of ion sources, respectively; a vacuum pump set is connected to the top of the main vacuum cavity, a workpiece rest is installed at the bottom in the main vacuum cavity, and is used for installing a to-be-deposited sample piece; and an auxiliary anode is further installed in the main vacuum cavity.

Preferably, the main vacuum cavity is a cuboid cavity of 750 mm×6750 mm×850 mm.

Preferably, the auxiliary anode employs an anode bar, and four corners in the main vacuum cavity are each provided with the anode bar.

Preferably, the anode bar is connected to an adjustable forward bias power supply, and the adjustable forward bias power supply has a voltage of 0-500 V.

Preferably, the vacuum cavity door employs a clamshell type side-opening door.

Preferably, the ion source is connected to an adjustable power supply which has a voltage of 0-2000 V and a frequency of 20 KHz, and the adjustable power supply can provide a DC symmetric pulse power supply; and the power waveform of the DC symmetric pulse power supply is a sine wave or rectangular wave.

Preferably, the opposite electromagnetic coils at the two sides of each of the ion sources are powered by a set of DC/DC symmetric pulse power supply, and the power waveform of the DC/DC symmetric pulse power supply is a sine wave or a rectangular wave.

Preferably, the magnetron sputtering target is installed at one side, away from the main vacuum cavity, of the vacuum cavity door, and the magnetron sputtering target is connected to a micro-pulse magnetron sputtering power supply of 20 KW, with a pulse duty ratio of less than 50%.

Preferably, the workpiece rest employs a planet revolution device.

An electromagnetic separation type coating method is further disclosed, which comprises the following steps:

step one, cleaning a deposited sample piece, installing the sample piece on a workpiece rest, and vacuumizing a main vacuum cavity;

step two, setting the revolving speed of the workpiece rest, and introducing argon into the main vacuum cavity to reach the set pressure;

step three, turning on an adjustable power supply connected to an ion source, and turning on an electromagnetic coil power supply;

step four, maintain a bias power supply applied to the deposited sample piece at a set voltage, and cleaning the deposited sample piece by bombarding with argon ions;

step five, turning on a power supply of a magnetron sputtering target, and setting time for Ti metal ion implantation deposition;

step six, adjusting a bias voltage, and depositing metal Ti;

step seven, introducing nitrogen, and depositing titanium nitride; and

step eight, turning off an electromagnetic separation type coating device, introducing the nitrogen, and introducing air after the temperature in the main vacuum cavity is reduced to a set temperature, and opening the main vacuum cavity to take out the deposited sample piece.

Compared to the prior art, the present disclosure has the following technical effects:

the electromagnetic separation type coating device is an electromagnetic separation type magnetron sputtering/ion source composite deposition system, plasma excited by magnetron sputtering or an ion source flies to a deposited sample piece under the constraint of a magnetic field generated by an electromagnetic coil, thus growing a thin film on the deposited sample piece; in the process that the plasma flies to the deposited sample piece, electrons are absorbed by the auxiliary anode, positive ions spirally accelerate to move along magnetic induction lines to achieve the separation of the electrons and the ions; the electromagnetic coils form opposite closed magnetic fields, respectively, the magnetic fields are periodically inverted along with time, and the magnetic field reversal leads to the plasma oscillation, which further accelerates the ionization of neutral particles. Under the combined action of the positive electric field and the oscillating magnetic field, the electrons in the plasma are separated from ions to increase the probability of colliding with the neutral particles, thus improving the ionization rate and the ion energy; the plasma density is improved by about 5 times or above, the three-dimensional plasma density is effectively improved, the ion energy is increased, and the thin film with excellent performance is ultimately obtained in the deposition process. Meanwhile, the usage amount of reactive gas is reduced, and the target poisoning is inhibited.

### BRIEF DESCRIPTION OF THE DRAWINGS

To describe the technical solutions in the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a structure diagram of an electromagnetic separation type coating device in the present disclosure;

FIG. 2 is a waveform diagram of a high-power micro-pulse magnetron sputtering power supply of the present disclosure;

FIG. 3 is an oscillation diagram of magnetic field reversal changing along with power supply waveform in the present disclosure.

In the drawings: 1—main vacuum cavity, 2—vacuum cavity door, 3—magnetron sputtering target, 4—ion source, 5—magnetic induction coil, 6—vacuum pump set, 7—workpiece rest, 8—anode bar.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by those of ordinary skill in the art based on the embodiments of the present disclosure without creative efforts shall fall within the protection scope of the present disclosure.

An objective of the present disclosure is to provide an electromagnetic separation type coating device and method to solve the problems in the prior art, which can effectively improve the three-dimensional space plasma density, increase the ion energy, and obtain a thin film with excellent performance.

To make the objective, the features and advantages of the present disclosure more obvious and understandable, the following further describes the present disclosure in detail with reference to the accompanying drawings and specific embodiments.

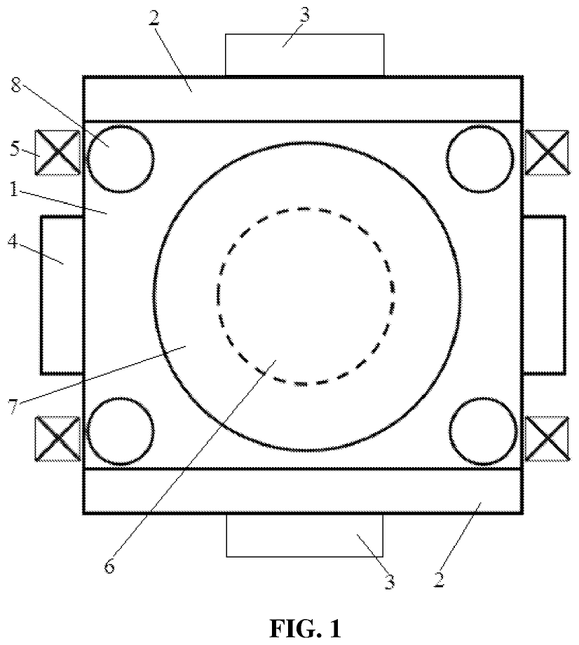

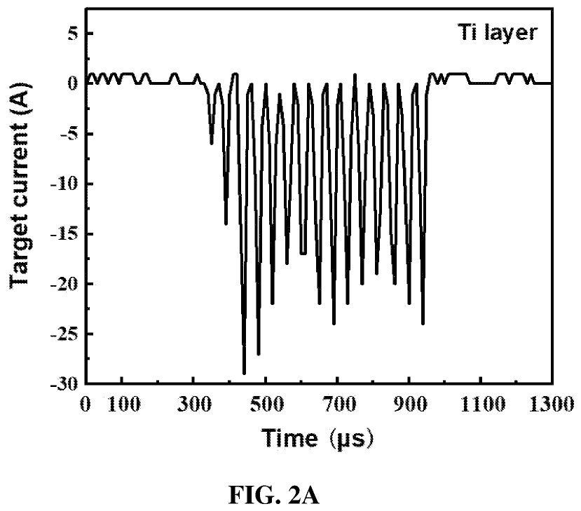

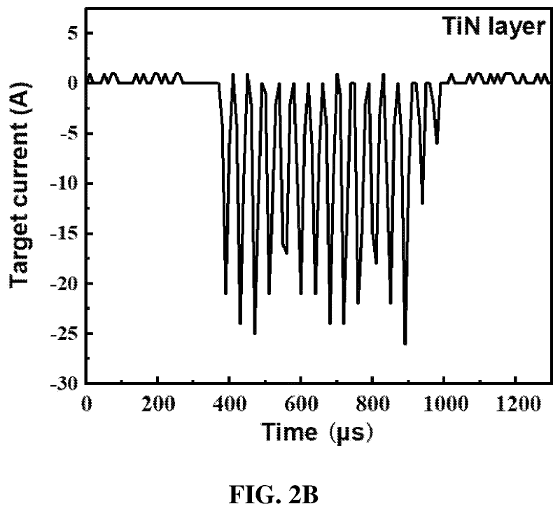

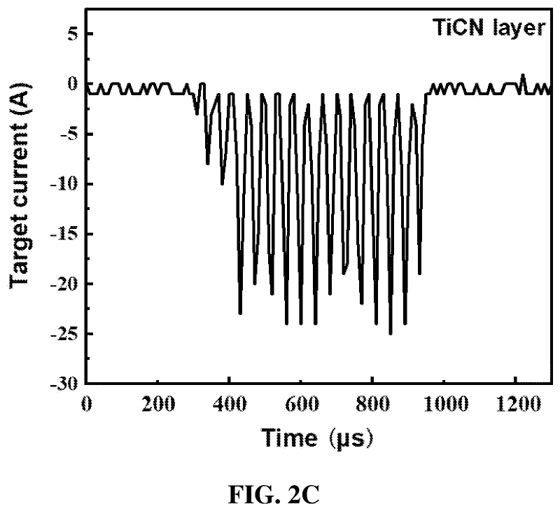

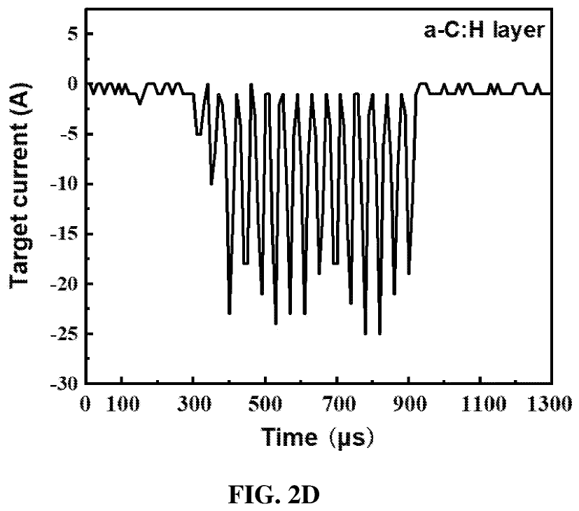

As shown in FIGS. 1-3, an electromagnetic separation type coating device comprises a main vacuum cavity 1, wherein four corners in the main vacuum cavity 1 are each provided with an anode bar 8 as an auxiliary anode; a vacuum pump set 6 and a workpiece rest 7 are installed in the main vacuum cavity 1, and the vacuum pump set 6 is located at the top of the main vacuum cavity 1; two opposite side walls in four side walls of the main vacuum cavity 1 form a side wall set, wherein two side walls in one side wall set are each provided with a vacuum cavity door 2, magnetron sputtering targets 3 are installed on side faces, away from the main vacuum cavity 1, of the two vacuum cavity doors 2, and the two magnetron sputtering targets 3 are symmetrically arranged; ion sources 4 are installed on two side walls in another side wall set, and the two sets of ion sources 4 are symmetrically arranged; two sets of magnetic induction coils 5 are further installed on the side walls where the ion source 4 is located, and the two sets of magnetic induction coils 5 installed on the same side wall are symmetrically arranged with respect to the ion source 4 installed on the side wall.

In this embodiment, the vacuum cavity door 2 employs a clamshell type side-opening door, or side-opening doors of other structures according to working requirements.

In this embodiment, the magnetron sputtering target 3 is connected to a micro-pulse magnetron sputtering power supply of 20 KW, with a pulse duty ratio of less than 50%.

In this embodiment, the ion source 4 is a rectangular ion source with the length 180 mm×the width 600 mm, a magnetic field of the ion source is N, and the magnetic field intensity of a slit is 400-600 Gauss; the ion source 4 is connected to an adjustable power supply with the voltage of 0-2000 V and the frequency of 20 KHz, and the adjustable power supply provides a DC symmetrical pulse power supply, and the power waveform can be a sine wave, a rectangular wave, and the like.

In this embodiment, the coil of the magnetic induction coil 5 is 5000 ampere-turns, with the dimension of 360 mm×600 mm; and the magnetic induction coil 5 is connected to a high-power DC pulse power supply having the current of 0-100 A.

In this embodiment, the anode bar 8 is connected to the adjustable forward bias power supply having the voltage of 0-500 V, and the anode bar 8 has a diameter of 60 mm and a length of 750 mm.

In this embodiment, the main vacuum cavity 1 is a cuboid cavity having the dimension of length 750 mm×width 750 mm×850 mm.

In this embodiment, the magnetron sputtering target 3 is a rectangular magnetron target having length 175 mm×width 600 mm, magnetic field directions are in SNNSNNS arrangement, with spacing distances of 6 mm, 24 mm, 6 mm, 6 mm, 24 mm, 6 mm.

In this embodiment, the vacuum pump set 6 employs a FF250-2000 molecular pump+18 L/min mechanical pump, which meets the condition of vacuumizing to 2×10⁻³ Pa in 40 minutes.

In this embodiments, the workpiece rest 7 is arranged at the bottom of the main vacuum cavity 1 and is a planet revolution device; specifically, the workpiece rest 7 can be rotatably installed at the bottom in the main vacuum cavity 1 through a rotating mechanism such as a rotating shaft; a plurality of stations are provided on the workpiece rest 7, trays are rotatably installed on the stations, and deposited sample pieces can be installed on the trays; when the workpiece rest 7 revolves, the trays on the stations can also rotate, thus driving the deposited sample pieces to rotate; wherein the workpiece rest 7 can be connected to a driving mechanism such as a driving motor, and the workpiece rest 7 and the trays are driven by the driving mechanism to rotate. Or the workpiece rest 7 may also employ workpieces of other structures according to working requirements.

A coating method based on the electromagnetic separation type coating device is further disclosed in the embodiment, which comprises the following steps:

cleaning a deposited sample piece and installing the deposited sample piece on a workpiece rest 7, vacuumizing to 2×10⁻³ Pa; setting the revolving speed of the workpiece rest 7 to be 2 circles/min, introducing argon into a main vacuum cavity 1 to the pressure of 0.5 Pa, turning on an adjustable power supply connected to an ion source 4, and setting a voltage to be 1500 V; setting the anode bias to be +300V, the frequency to be 10 KHz, and the electromagnetic field current to be 80 A; keeping a bias power supply applied to the deposited sample piece at voltage of −500 V, and cleaning the deposited sample piece by bombarding with argon ions for 20 minutes;

in the cleaning process, measuring the plasma density with the anode bias and without the magnetic field, the plasma density with the magnetic field and without the anode bias and the plasma density with the anode and the electromagnetic field, wherein the plasma density is improved by more than 2 times, more than 2.2 times and more than 5 times respectively in comparison with the plasma density only with the electromagnetic coil, the plasma density only with the anode, and the plasma density without the electromagnetic coil and the anode field;

keeping the conditions unchanged, turning on a high-power micro-pulse magnetron sputtering power supply (magnetron sputtering Ti target), setting the voltage to be 650 V, the pulse length to be 2000 ms, the duty ratio to be 45%, and the Ti metal ion implantation deposition time to be 10 min;

adjusting the bias to −60 V, and depositing the metal Ti for 30 min;

introducing the nitrogen, the flow rate of which is about 5% of the flow rate of the argon, and depositing the titanium nitride for 120 min; and

then turning off the system, introducing the nitrogen, and then introducing the air until the temperature in the main vacuum cavity 1 is reduced to 50° C.; and opening the main vacuum cavity 1 to take out the deposited sample piece.

The deposited sample piece is golden yellow after being inspected by naked eyes, and when the golden yellow titanium nitride is prepared through traditional magnetron sputtering, the flow rate of the nitrogen needs to account for more than 15% of the flow rate of the argon, thus the usage amount of reactive gas is effectively reduced, and the hardness of the obtained thin film is 35 GPa which is higher than 27 GPa of traditional sputtering.

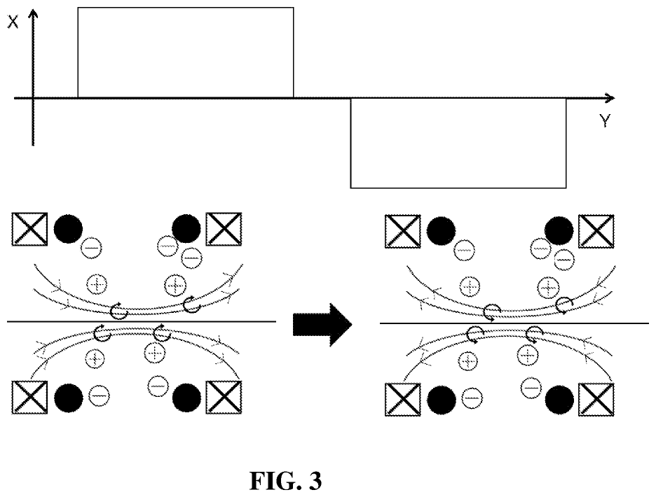

As shown in FIG. 3, in the coating process of the embodiment, electrons in the plasma are absorbed by the adjacent anode bar 8 while the plasma generated by the ion source 4 is constrained and compressed by the magnetic field generated by the magnetic induction coil 5, thus the neutralization of positive and negative charges is reduced, and the gas ionization rate and the plasma energy and density are improved. The magnetic induction coil 5 of the ion source is powered by a set of DC/DC pulse, and the power waveform may be sine waves, rectangular waves, and the like, thus achieving the periodic reversal of the electromagnetic field. On the one hand, the electrons in the plasma are absorbed by the adjacent anode bar 8 while the plasma formed by the ion source is constrained and compressed by the magnetic field, thus the neutralization of positive and negative charges is reduced, and the gas ionization rate and the plasma energy and density are improved; on the other hand, in magnetron sputtering, the magnetic field and periodically reversed oscillating electromagnetic field form closed and unclosed plasma oscillation, the electrons in the plasma are absorbed by the anode bars 8, thus the neutralization of positive and negative charges is eliminated, and the gas ionization rate and plasma energy and density are improved.

In the plasma generated by the ion source 4, on the one hand, the negatively charged electrons are accelerated and absorbed by the anode bar 8, the collision probability of the electrons and neutral particles is increased, and the neutralization possibility of positive and negative charged ions in the plasma is reduced; on the other hand, the positively charged ions move along the magnetic lines of force and are accelerated to collide with the neutral ions under the oscillation of the reversing magnetic field. Therefore, under the combined action of a positive electric field and an oscillating magnetic field, the electrons in the plasma are separated from the ions to increase the collision probability with neutral particles, thus the ionization rate and the ion energy are improved, the plasma density is improved by about 5 times or above, the usage amount of the reactive gas is reduced, and target poisoning is inhibited.

Several examples are used for illustration of the principles and implementation methods of the present disclosure. The description of the embodiments is merely used to help illustrate the method and its core principles of the present disclosure. In addition, those of ordinary skill in the art can make various modifications in terms of specific embodiments and scope of application in accordance with the teachings of the present disclosure. In conclusion, the content of the specification should not be construed as a limitation to the present disclosure.

1. An electromagnetic separation type coating device, comprising:
a main vacuum cavity, wherein the front side and the rear side of the main vacuum cavity are each provided with a vacuum cavity door, middle positions of the front vacuum cavity door and the rear vacuum cavity door are each provided with a magnetron sputtering target, and the two magnetron sputtering targets are symmetrically arranged;
two ion sources that are symmetrically arranged on the outer walls of the left side and the right side of the main vacuum cavity;
two magnetic induction coils that are symmetrically arranged at two sides of each of the ion sources, respectively;
a vacuum pump set that is connected to the top of the main vacuum cavity;
a workpiece rest that is installed at the bottom in the main vacuum cavity, and is used for installing a to-be-deposited sample piece; and
an auxiliary anode that is installed in the main vacuum cavity.

2. The electromagnetic separation type coating device according to claim 1, wherein the main vacuum cavity is a cuboid cavity of approximately 750 mm×6750 mm×850 mm.

3. The electromagnetic separation type coating device according to claim 2, wherein the auxiliary anode employs a plurality of anode bars, and four corners in the main vacuum cavity are each provided with an anode bar from the plurality of anode bars.

4. The electromagnetic separation type coating device according to claim 3, wherein one or more of the plurality of anode bars is connected to an adjustable forward bias power supply, and the adjustable forward bias power supply has a voltage of 0-500 V.

5. The electromagnetic separation type coating device according to claim 1, wherein the vacuum cavity door employs a clamshell type side-opening door.

6. The electromagnetic separation type coating device according to claim 1, wherein each ion source is connected to an adjustable power supply which has a voltage of 0-2000 V and a frequency of 20 KHz, and the adjustable power supply can provide DC symmetric pulse power; and the power waveform of the DC symmetric pulse power is a sine wave or a rectangular wave.

7. The electromagnetic separation type coating device according to claim 6, wherein the electromagnetic coils at the two sides of each of the ion sources are powered by a DC/DC symmetric pulse power supply, and the power waveform of the DC/DC symmetric pulse power supply is a sine wave or a rectangular wave.

8. The electromagnetic separation type coating device according to claim 1, wherein the magnetron sputtering target is installed on a side of the vacuum cavity door that is away from the main vacuum cavity, and the magnetron sputtering target is connected to a micro-pulse magnetron sputtering power supply of 20 KW, with a pulse duty ratio of less than 50%.

9. The electromagnetic separation type coating device according to claim 1, wherein the workpiece rest employs a planet revolution device.

10. An electromagnetic separation type coating method used with an electromagnetic separation type coating device, the method comprising:
cleaning a sample piece, installing the sample piece on a workpiece rest, and vacuumizing a main vacuum cavity;
setting the revolving speed of the workpiece rest, and introducing argon into the main vacuum cavity to reach a predetermined pressure;
turning on an adjustable power supply connected to an ion source, and turning on an electromagnetic coil power supply;
maintaining a bias power supply applied to the sample piece at a predetermined voltage, and cleaning the sample piece by bombarding with argon ions;
turning on a power supply of a magnetron sputtering target, and setting a time for titanium (Ti) metal ion implantation deposition;
adjusting a bias voltage, and depositing metal Ti;
introducing a first quantity of nitrogen, and depositing titanium nitride; and
turning off the electromagnetic separation type coating device, introducing a second quantity of nitrogen, introducing air after the temperature in the main vacuum cavity is reduced to a predetermined temperature, and opening the main vacuum cavity to take out the sample piece that has been deposited.
